(19) United States
(12) Patent Application Publication
(10) Pub. No.: US 2025/0020690 A1
(43) Pub. Date: Jan. 16, 2025

(54) GUIDE MEMBER, INSPECTION DEVICE, AND ELECTRO-CONDUCTIVE CONTACT PIN

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Sung Hyun BYUN, Gyeonggi-do (KR)

(73) Assignee: POINT ENGINEERING CO., LTD., Chungcheongnam-do (KR)

(21) Appl. No.: 18/764,351

(22) Filed: Jul. 4, 2024

(30) Foreign Application Priority Data
Jul. 10, 2023 (KR) 10-2023-0089318

(51) Int. Cl. G01R 1/067

(52) U.S. Cl. CPC G01R 1/06716

(57) ABSTRACT

A guide member, an inspection device, and an electro-conductive contact pin for improving inspection reliability with respect to an inspection object are proposed.

### CROSS REFERENCE TO RELATED APPLICATIONS

The present application claims priority to Korean Patent Application No. 10-2023-0089318, filed Jul. 10, 2023, the entire contents of which is incorporated herein for all purposes by this reference.

### BACKGROUND

### 1. Technical Field

The present disclosure relates to a guide member, an inspection device, and an electro-conductive contact pin.

### 2. Description of the Related Art

Electrical property test of a semiconductor element is performed by bringing an inspection object (semiconductor wafer or semiconductor package) to an inspection device including a plurality of electro-conductive contact pins and bringing the electro-conductive contact pin into contact with a relevant external terminal (solder ball, bump, or the like) on the inspection object. An example of the inspection device may include a probe card, a test socket, or an interposer, but is not limited thereto.

The conventional test socket may include a pogo-type test socket and a rubber-type test socket.

An electro-conductive contact pin (hereinbelow, ‘pogo-type socket pin’) used in the pogo-type test socket includes a pin part and a barrel containing the pin part. In order to move the pin part in the barrel in a sliding manner, a gap should be provided between an outer surface of the pin part and an inner surface of the barrel. However, since the pogo-type socket pin including the barrel and the pin part which are separately formed and then coupled to each other is used, management of the gap cannot be precisely performed as the outer surface of the pin part and the inner surface of the barrel are spaced apart from each other more than necessary. Therefore, in a process in which electric signals are transmitted to the barrel through plungers at opposite ends, electrical signals are lost and distorted, and a problem of inconsistent contact stability occurs.

Meanwhile, an electro-conductive contact pin (hereinbelow, ‘rubber-type socket pin’) used in the rubber-type test socket has a structure in which conducive micro balls are arranged inside a silicone rubber made of rubber. When an inspection object (for example, a semiconductor package) is placed and then the socket is closed so that stress is applied, as the gold-based conductive micro balls press each other strongly, conduction increases, and electrical connection is achieved. However, the rubber-type socket pin is problematic in that contact stability can only be ensured when pressed with excessive pressure.

Meanwhile, recently, with the advancement and high integration of semiconductor technology, narrower pitches of external terminals of the inspection object are progressing further. However, the conventional rubber-type socket pin is formed by preparing a molding material with conductive particles distributed within a fluid elastic material, inserting the molding material into a predetermined mold, and then arranging the conductive particles in a thickness direction by applying a magnetic field in the thickness direction. Therefore, when the gap between magnetic fields narrows, the conductive particles are irregularly oriented and a signal flows in a planar direction. Therefore, there is a limitation in responding to the narrow pitch technology trend with the existing rubber-type socket pin.

Furthermore, since the pogo-type socket pin is formed and used with the barrel and the pin part which are separately prepared and then coupled to each other, there is a problem in that the pogo-type socket pin is formed into a small size. Therefore, also, there is a limitation in responding to the narrow pitch technology trend with the existing pogo-type socket pin.

### DOCUMENTS OF RELATED ART

(Patent Document 1) Korean Patent No. 10-0659944
(Patent Document 2) Korean Patent No. 10-0952712

### SUMMARY

Accordingly, the present disclosure has been made keeping in mind the above problems occurring in the related art, and an objective of the present disclosure is to a guide member, an inspection device, and an electro-conductive contact pin, which are provided to improve the inspection reliability of an inspection object.

Another objective of the present disclosure is to provide a guide member, an inspection device, and an electro-conductive contact pin, which are provided to prevent the electro-conductive contact pin from being separated from the guide member.

In order to achieve the above-described objectives, according to an embodiment of the present disclosure, there is provided a guide member to which an electro-conductive contact pin is coupled, the guide member including: a through hole containing the electro-conductive contact pin, wherein the through hole may include: a first region formed by extending in a thickness direction along the guide member; and a second region provided on the first region and formed by extending in a width direction along one surface of the guide member.

The second region may include a plurality of second regions and the plurality of second regions may be arranged in the thickness direction, the first region may include a plurality of first regions and the plurality of first regions may be arranged in the width direction, and the plurality of second regions may communicate with the first region to form a plurality of through holes.

Meanwhile, according to an embodiment of the present disclosure, there is provided an inspection device for inspecting electrical properties of an inspection object, the inspection device including: an electro-conductive contact pin sending an electrical signal to the inspection object; and a guide member including a through hole containing the electro-conductive contact pin, wherein the electro-conductive contact pin may include a first connection part constituting a lower part, a second connection part constituting an upper part, and an elastic part connecting the first connection part and the second connection part to each other, wherein the through hole may include: a first region formed by extending in a thickness direction along the guide member; and a second region provided on the first region and formed by extending in a width direction along one surface of the guide member.

The elastic part may be located between an upper surface and a lower surface of the guide member.

The guide member may include a fixing step formed by the first region and the second region, and the electro-conductive contact pin may further include: a first locking step formed by protruding in the width direction at a first location of the contact pin; and a second locking step formed by protruding in the width direction at a second location of the contact pin, an upper surface of the fixing step may be in contact with the second locking step to limit separation of the electro-conductive contact pin, and a lower surface of the fixing step may be in contact with the first locking step to limit separation of the electro-conductive contact pin.

The first locking step may move inward in the width direction to pass through the first region in a longitudinal direction.

Meanwhile, according to an embodiment of the present disclosure, there is provided an electro-conductive contact pin including: a division part extending in a width direction; a support part extending in a longitudinal direction from either side of the division part; a first connection part provided at a lower part of the division part; a second connection part provided at an upper part of the division part; a first extension part extending in the longitudinal direction from either side of the first connection part; a second extension part extending in a longitudinal direction from either side of the second connection part; and an elastic part connecting the division part and the first connection part to each other and connecting the division part and the second connection part to each other, wherein when the elastic part is compressed, a current path may be formed by at least one of contact between the support part and the first extension part and contact between the support part and the second extension part.

The first extension part may be formed by being spaced apart from the support part along an inner surface of the support part, the second extension part may be formed by being spaced apart from the support part along the inner surface of the support part, and the first extension part and the second extension part may be in contact with the support part to limit the width-directional excessive deformation of the electro-conductive contact pin.

The first extension part may include a 1-1 extension part extending from a first side of the first connection part and a 1-2 extension part extending from a second side of the first connection part, at least one of the 1-1 extension part and the 1-2 extension part may include a first contact part bent in the width direction, and the first contact part may be contactable with the support part according to compression of the elastic part.

The second extension part may include a 2-1 extension part extending from a first side of the second connection part and a 2-2 extension part extending from a second side of the second connection part, at least one of the 2-1 extension part and the 2-2 extension part may include a second contact part bent in the width direction, and the second contact part may be contactable with the support part according to compression of the elastic part.

The present disclosure can provide the effects of preventing separation between the electro-conductive contact pin and the guide member and increasing the inspection reliability of an inspection object when inspection for an inspection object is performed.

### BRIEF DESCRIPTION OF THE DRAWINGS

FIG. 1 is a view illustrating an electro-conductive contact pin according to an embodiment of the present disclosure.

FIG. 2 is a view illustrating the electro-conductive contact pin according to the embodiment of the present disclosure.

FIG. 3 is a view illustrating a current path formed by the electro-conductive contact pin in the embodiment of the present disclosure.

FIG. 4 is a view illustrating the entire shape of a guide member according to the embodiment of the present disclosure.

FIG. 5 is a view illustrating a lower surface of the guide member according to the embodiment of the present disclosure.

FIG. 6 is a view illustrating an upper surface of the guide member according to the embodiment of the present disclosure.

FIG. 7 is a view illustrating the guide member to which the electro-conductive contact pin is coupled in the embodiment of the present disclosure.

FIG. 8A is a view illustrating an inspection device before the electro-conductive contact pin is coupled to the guide member in the present disclosure.

FIG. 8B is a view illustrating the inspection device after the electro-conductive contact pin is coupled to the guide member in the embodiment of the present disclosure.

FIG. 9 is a view illustrating the inspection device according to the embodiment of the present disclosure and a partial section thereof.

### DETAILED DESCRIPTION

Hereinbelow, the following illustrates the principle of the present disclosure. Those skilled in the art will be able to embody the principle of the present disclosure and invent various apparatuses included in the spirit and the scope of the present disclosure, although not shown herein. Further, all conditional terms and embodiments described herein are clearly intended for the purpose of understanding the concept of the present disclosure, and should be understood not to be limited to the specifically listed embodiments and states.

The above and other objectives, features and advantages of the present disclosure will be more clearly understood from the following detailed description taken in conjunction with the accompanying drawings.

The embodiments described herein will be described with reference to sectional views and/or perspective views, which are ideal drawings of the present disclosure. The sizes of the configuration and device illustrated in the drawings are exaggerated for an effective description of the technical sprit of the present disclosure. Variations from the shapes of the illustrations as a result, for example, of manufacturing techniques and/or tolerances, are to be expected.

Therefore, the embodiments of the present disclosure are not limited to the specific forms shown in the drawings, but include the changes in the forms caused by manufacturing processes. The technical terms used in the specification are used to describe specific embodiments, and thus are not intended to limit the present disclosure.

Hereinafter, in describing various embodiments, the same names and the same reference numbers will be used to refer to components that perform the same function even when the embodiments are different. Moreover, configuration and operation already described in other embodiments will be omitted for convenience.

Meanwhile, the expression “at least one of A, B, and C” means configuration consisting of one, two, or three selected from a group consisting of A, B, and C. Even when an element is expressed in a singular form, the element may be interpreted as a concept including plural elements. The expression “at least a part of D” may mean the entire or a part of D. Furthermore, in the specification, the width direction is +x and −x directions, the longitudinal direction is +y and −y directions, and the thickness direction is +z and −z directions.

First, the electro-conductive contact pin 100 (hereinbelow, “the electro-conductive contact pin”) will be described according to the embodiment of the present disclosure.

The electro-conductive contact pin 100 is provided in an inspection device 10 and may be used to send an electrical signal by being electrically and physically in contact with an inspection object. The inspection device 10 may be a device used in a semiconductor manufacturing process, e.g., a probe card, a test socket, or an interposer.

The electro-conductive contact pin 100 may be coupled to a guide member 200 to be used as a part of components of a probe card, a test socket, or an interposer. The electro-conductive contact pin 100 may be a probe pin provided in a probe card, a socket pin provided in a test socket, or a conductive pin provided in an interposer.

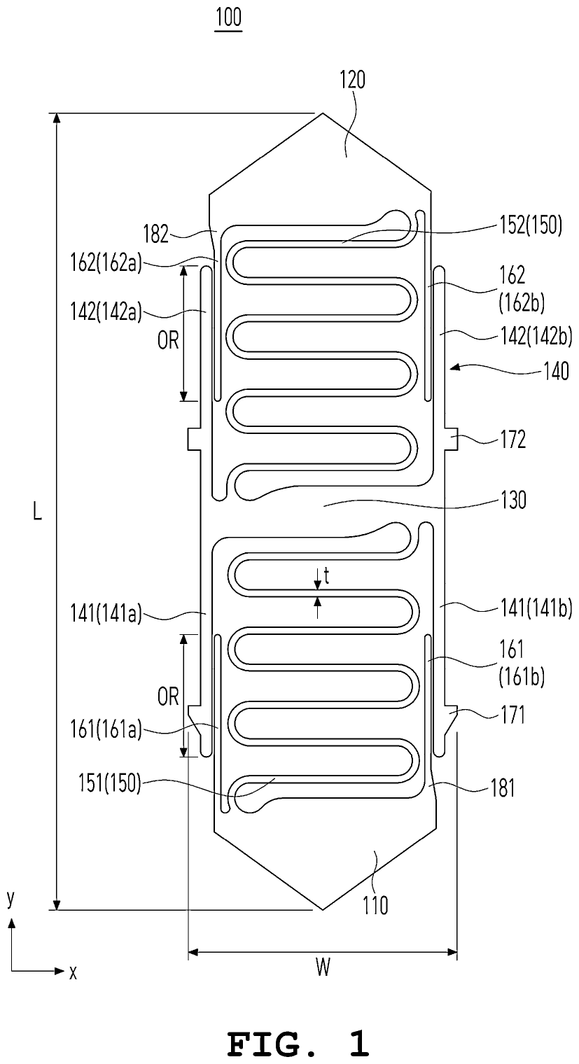

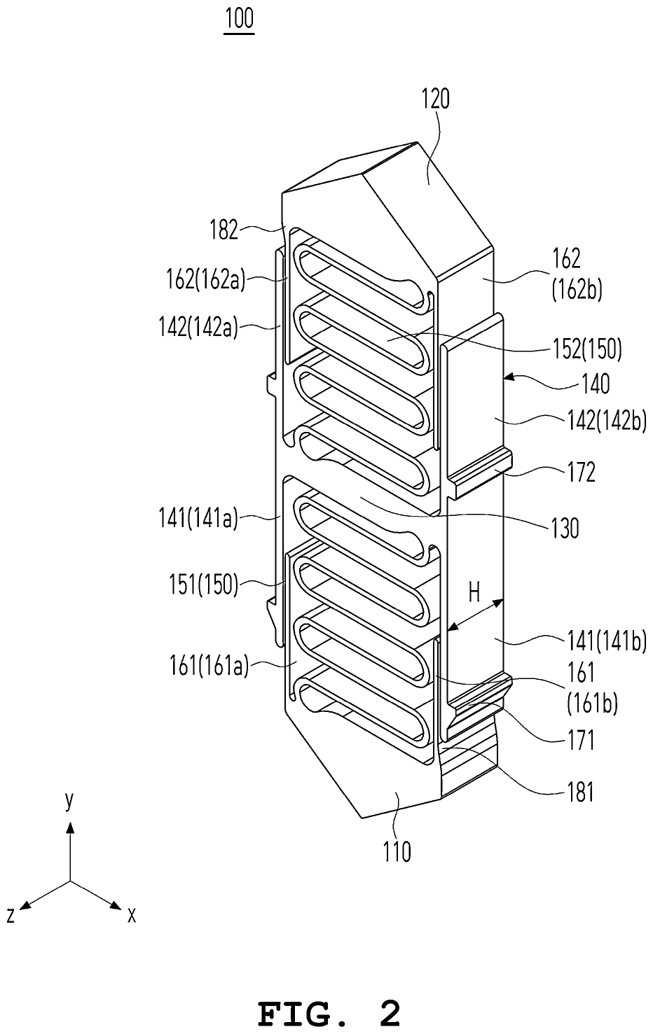

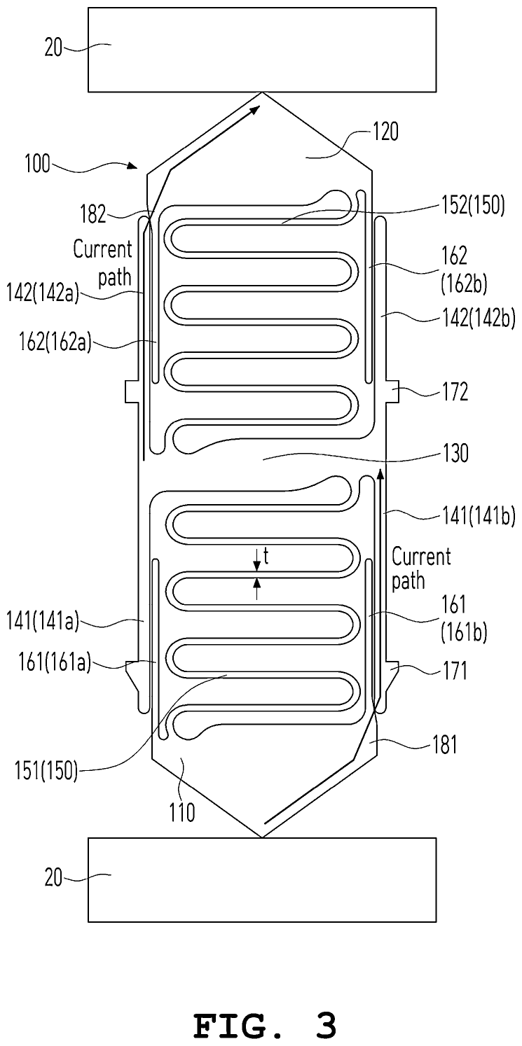

FIG. 1 is a view illustrating the electro-conductive contact pin 100 according to an embodiment of the present disclosure. FIG. 2 is a view illustrating the electro-conductive contact pin 100 according to an embodiment of the present disclosure. FIG. 3 is a view illustrating a current path formed by the electro-conductive contact pin 100 in the embodiment of the present disclosure.

Referring to FIGS. 1 and 2, the electro-conductive contact pin 100 may include: a division part 130 extending in a width direction; a support part 140 extending in a longitudinal direction from either side of the division part 130; a first connection part 110 provided at a lower part of the division part 130; a second connection part 120 provided at an upper part of the division part 130; a first extension part 161 extending in a longitudinal direction from either side of the first connection part 110; a second extension part 162 extending in a longitudinal direction from either side of the second connection part 120; and an elastic part 150 connecting the division part 130 and the first connection part 110 to each other and connecting the division part 130 and the second connection part 120 to each other.

The division part 130 may extend in the width direction (±x direction). The division part 130 may be coupled to the elastic part 150, 152 with a groove depressed in a downward direction on an upper portion of a first side thereof. The division part 130 may be coupled to the elastic part 150, 151 with a groove depressed in an upward direction on a lower portion of a second side thereof.

The support part 140 may extend in the longitudinal direction (±y direction) from either side of the division part 130. The support part 140 may include a first support part 141 and a second support part 142. The first support part 141 may include a 1-1 support part 141a and a 1-2 support part 141b. The second support part 142 may include a 2-1 support part 142a and a 2-2 support part 142b.

The 1-1 support part 141a may be provided at a first side of the division part 130 and extend in the longitudinal direction (−y direction). The 1-2 support part 141b may be provided at a second side of the division part 130 and extend in the longitudinal direction (−y direction). The 2-1 support part 142a may be provided at the first side of the division part 130 and extend in the longitudinal direction (+y direction). The 2-2 support part 142b may be provided at the second side of the division part 130 and extend in the longitudinal direction (+y direction).

The 1-1 support part 141a, the 1-2 support part 141b, the 2-1 support part 142a, and the 2-2 support part 142b may extend in the longitudinal direction of the electro-conductive contact pin 100 and be integrally connected to the division part 130 extending in the width direction of the electro-conductive contact pin 100.

Based on the division part 130, the 1-1 support part 141a and the 1-2 support part 141b constituting the lower part of the support part 140 may be elastically deformed in a direction (the width direction) in which the 1-1 support part 141a and the 1-2 support part 141b come closer to each other. Based on the division part 130, the 2-1 support part 142a and the 2-2 support part 142b constituting the upper part of the support part 140 may be elastically deformed in a direction (the width direction) in which the 2-1 support part 142a and the 2-2 support part 142b come closer to each other. Through the support part 140, a coupling process, in which the electro-conductive contact pin 100 is contained in a through hole 210 of the guide member 200 and coupled to the guide member 200, and a replacing process may be performed more easily.

The electro-conductive contact pin 100 may include a lower space and an upper space based on the division part 130 by the division part 130 and the support part 140 provided at either side of the division part 130.

The first connection part 110 may be located in the lower space and provided at the lower part of the division part 130. The second connection part 120 may be located in the upper space and provided at the upper part of the division part 130.

The first connection part 110 may be in contact with an external terminal (not shown) of an inspection object, and the second connection part 120 may be in contact with or connected to an external terminal (not shown) of a space transformer. On the other hand, the first connection part 110 may be in contact with or connected to the external terminal of the space transformer, and the second connection part 120 may be in contact with or connected to the external terminal of the inspection object. In other words, the first connection part 110 and the second connection part 120 may directly or indirectly transmit a current to the inspection object so that the inspection device 10 inspects the electrical properties of the inspection object.

Furthermore, the first connection part 110 may be in contact with or connected to the external terminal of the space transformer, and the second connection part 120 may be in contact or connected to an external terminal of a circuit board. On the other hand, the first connection part 110 may be in contact with or connected to the external terminal, and the second connection part 120 may be in contact with or connected to the external terminal of the space transformer. In other words, the first connection part 110 and the second connection part 120 indirectly send a current to the inspection object as interposers to inspect the electrical properties of the inspection object. Hereinbelow, all the above-described external terminals will be referred to as terminals 20.

The elastic part 150 may connect the division part 130 to the first connection part 110 and connect the division part 130 to the second connection part 120. In other words, the elastic part 150 a first elastic part 151 connecting the division part 130 to the first connection part 110, and a second elastic part 152 connecting the division part 130 to the second connection part 120.

The first elastic part 151 may be provided at the lower space and may connect the division part 130 and the first connection part 110 to each other. A first end part of the first elastic part 151 may be connected to a first side (left side or right side) of the division part 130. A second end part of the first elastic part 151 may be connected to a second side (right side or left side) of the first connection part 110. Herein, the first side and the second side may be based on a longitudinal shaft (y-axis) passing through the center of the width. The first end part and the second end part of the first elastic part 151 are connected to locations different in the width direction, thereby preventing the electro-conductive contact pin 100 from being excessively deformed in one direction.

The first elastic part 151 may be elastically deformed by being compressed or stretched based on the division part 130. When the first elastic part 151 is compressively deformed, the division part 130 fixed by the support part 140 may limit movement of the first elastic part 151.

The second elastic part 152 is provided in the upper space and may connect the division part 130 and the second connection part 120 to each other. A first end part of the second elastic part 152 may be connected to a second side (right side or left side) of the division part 130. A second end part of the second elastic part 152 may be connected to a first side of (left side or right side) of the second connection part 120. Herein, the first side and the second side may be based on a longitudinal shaft (y-axis) passing through the center of the width. The first end part and the second end part of the second elastic part 152 are connected to locations different in the width direction, thereby preventing the electro-conductive contact pin 100 from being excessively deformed in one direction.

In the embodiment, a lower end part of the first elastic part 151 may be connected to a first side part of the first connection part 110, an upper end part of the first elastic part 151 may be connected to a second side part of the division part 130, a lower end part of the second elastic part 152 may be connected to a first side of the division part 130, and an upper end part of the second elastic part 152 may be connected to the second side of a second connection part 120. Accordingly, unidirectional excessive deformation of the electro-conductive contact pin 100 may be prevented.

Based on the division part 130, the electro-conductive contact pin 100 may be divided into a region corresponding to the lower space with the first elastic part 151, and a region corresponding to the upper space with the second elastic part 152. The division part 130 may prevent foreign materials introduced toward the first elastic part 151 from being introduced toward the second elastic part 152, and prevent foreign materials introduced toward the second elastic part 152 from being introduced toward the first elastic part 151.

The first extension part 161 may extend from either side of the first connection part 110 in the longitudinal direction. The first extension part 161 may include a 1-1 extension part 161a extending from a first side of the first connection part 110 in the longitudinal direction (+y direction) and a 1-2 extension part 161b extending from a second side of the first connection part 110 in the longitudinal direction (+y direction).

The first extension part 161 may be formed along an inner surface of the first support part 141 and spaced apart from the first support part 141. The 1-1 extension part 161a may be formed along an inner surface of the 1-1 support part 141a and spaced apart from the 1-1 support part 141a. The 1-2 extension part 161b may be formed along an inner surface of the 1-2 support part 141b and spaced apart from the 1-2 support part 141b. In other words, the first extension part 161 and the first support part 141 may form an overlapping region OR in a certain section.

When the elastic part 150 is compressed and the electro-conductive contact pin 100 is elastically deformed in the width direction and/or the longitudinal direction, the first extension part 161 is in contact with the first support part 141 to prevent the electro-conductive contact pin 100 from being excessively deformed in the width direction and/or the longitudinal direction.

The second extension part 162 may extend from either side of the second connection part 120 in the longitudinal direction. The second extension part 162 may include a 2-1 extension part 162a extending from a first side of the second connection part 120 in the longitudinal direction (−y direction) and a 2-2 extension part 162b extending from a second side of from the second connection part 120 in the longitudinal direction (−y direction).

The second extension part 162 may be formed along an inner surface of the second support part 142 and spaced apart from the second support part 142. The 2-1 extension part 162a may be formed along an inner surface of the 2-1 support part 142a and spaced apart from the 2-1 support part 142a, and the 2-2 extension part 162b may be formed along an inner surface of the 2-2 support part 142b and spaced apart from the 2-2 support part 142b. In other words, the second extension part 162 and the second support part 142 may form an overlapping region OR in a certain section.

When the elastic part 150 is compressed and the electro-conductive contact pin 100 is elastically deformed in the width direction and/or the longitudinal direction, the second extension part 162 is in contact with the second support part 142 to prevent the electro-conductive contact pin 100 from being excessively deformed in the width direction and/or the longitudinal direction.

Referring to FIG. 3, at least one of the 1-1 extension part 161a and the 1-2 extension part 161b may include a first contact part 181 bent in the width direction. The 1-1 extension part 161a and/or the 1-2 extension part 161b may be connected to the first connection part 110 via the first contact part 181.

The first contact part 181 may be provided to be bent inward in the width direction (+x or −x direction) from a first side end and/or a second side end of the first connection part 110, and form a current path by being in contact with an end part of the first support part 141. In other words, the first contact part 181 may be in contact with the support part 140 according to compression of the elastic part 150.

At least one of the 2-1 extension part 162a and the 2-2 extension part 162b may include a second contact part 182 bent in the width direction. The 2-1 extension part 162a and/or the 2-2 extension part 162b may be connected to the second connection part 120 via the second contact part 182.

The second contact part 182 may be provided to be bent inward in the width direction from a first side end and/or a second side end of the second connection part 120, and form the current path by being in contact with the second support part 142. In other words, the second contact part 182 may be in contact with the support part 140 according to compression of the elastic part 150.

In the embodiment, the first contact part 181 may be provided at the 1-2 extension part 161b connected to the first side of the first connection part 110, and the second contact part 182 may be provided at the 2-1 extension part 162a connected to the second side of the second connection part 120. Accordingly, unidirectional excessive deformation of the electro-conductive contact pin 100 may be prevented.

Furthermore, the first contact part 181 and the second contact part 182 may be in contact with the first support part 141 and the second support part 142 to form the current path, thereby increasing the electrical properties of the electro-conductive contact pin 100.

The division part 130, the support part 140, the first connection part 110, the second connection part 120, the first extension part 161, the second extension part 162, and the elastic part 150 may be integrally provided. The division part 130, the support part 140, the first connection part 110, the second connection part 120, the first extension part 161, the second extension part 162, and the elastic part 150 may be formed in a thickness direction by a plating process.

The electro-conductive contact pin 100 may be provided with one or a plurality of metal layers stacked in the thickness direction. When the electro-conductive contact pin 100 includes a plurality of metal layers, the plurality of metal layers may include a first metal layer (not illustrated) and a second metal layer (not illustrated).

The first metal layer may be made of a metal with relatively high wear resistance compared to the second metal layer. Preferably, the first metal layer may be formed of at least one metal selected from rhodium (Rd), platinum (Pt), iridium (Ir), palladium (Pd), nickel (Ni), manganese (Mn), tungsten (W), phosphorus (Ph), or an alloy thereof, or a palladium-cobalt (PdCo) alloy, a palladium-nickel (PdNi) alloy or a nickel-phosphorus (NiPh) alloy, a nickel-manganese (NiMn), a nickel-cobalt (NiCo), or a nickel-tungsten (NiW) alloy, copper (Cu), silver (Ag), gold (Au), or an alloy thereof. However, the first metal layer is not limited to the above-described materials.

The second metal layer may be provided with a metal with relatively high electrical conductivity compared to the first metal layer. Preferably, the second metal layer may be formed of a metal selected from copper (Cu), silver (Ag), gold (Au), or an alloy thereof. However, the second metal layer is not limited to the above-described materials.

The first metal layer may be provided on an upper surface and a lower surface in the thickness direction of the electro-conductive contact pin 100. The second metal layer may be provided between the first metal layer and another first metal layer. For example, the electro-conductive contact pin 100 may be provided with the first metal layer, the second metal layer, and the first metal layer alternately stacked in order. The electro-conductive contact pin 100 may be provided with a plurality of first metal layers and a plurality of second metal layers, and the plurality of first metal layers and the plurality of second metal layers may be alternately stacked.

Referring to FIG. 3 again, when the electro-conductive contact pin 100 is in contact with the terminals 20 to inspect an inspection object, the first connection part 110 and the second connection part 120 may be moved toward the division part 130 by compressive deformation of the elastic part 150. The elasticity of the elastic part 150 may prevent damage to the electro-conductive contact pin 100 and prevent damage to the terminals 20 and/or the inspection object.

Each of the first elastic part 151 and the second elastic part 152 may be formed by alternately connecting a plurality of linear parts and a plurality of curved parts. Each linear part may connect left and right adjacent curved parts to each other, and each curved part may connect upper and lower adjacent linear parts to each other. Each curved part may have a circular arc shape.

Each linear part may extend in the width direction and be arranged in the longitudinal direction. Each curved part may extend in the longitudinal direction and be bent outward in the width direction.

Each linear part may be provided in the width direction of the electro-conductive contact pin 100 so that elastic deformation of each curved part according to a contact pressure is performed more easily.

The first elastic part 151 and the second elastic part 152 may need the compression amount sufficient to allow stable contact with the terminals 20. Herein, the first elastic part 151 and the second elastic part 152 may be provided with different elastic coefficients. The first elastic part 151 and the second elastic part 152 may have different lengths. The first elastic part 151 and the second elastic part 152 may have different actual widths (t). The first elastic part 151 and/or the second elastic part 152 may include one or more elastic parts.

The entire length of the electro-conductive contact pin 100 may need to be shortened to efficiently correspond to a high frequency property inspection of an inspection object. An actual width (t) of the elastic part 150 may be formed small and an entire thickness size H thereof may be formed large.

Referring to FIGS. 1 and 2 again, the elastic part 150 may have the entire thickness size (H) formed larger than the actual width (t). Preferably, the actual width (t) of the elastic part 150 of the electro-conductive contact pin 100 may range from 5 μm to 15 μm, and the entire thickness size (H) may range from 70 μm to 200 μm. Herein, a ratio of the actual width (t) and the entire thickness size H may range from 1:5 to 1:30. However, the actual width (t) and the entire thickness size H are not limited to the above-described sizes and rates.

Accordingly, damage to the elastic part 150 may be prevented and the length of the elastic part 150 may be short. Even though the length of the elastic part 150 is short, the elastic part 150 may maintain appropriate contact pressure. Furthermore, with the entire thickness size H of the elastic part 150 larger than the actual width (t), resistance to a moment acting in the thickness direction of the elastic part 150 can be increased and contact stability can be improved.

As it is possible to shorten the length of the elastic part 150, a ratio of the entire thickness size H and the entire length size L of the electro-conductive contact pin 100 may be from 1:3 to 1:12. However, the sizes are not necessarily limited to the above-described ratios.

Accordingly, it is possible to make the entire length of the electro-conductive contact pin 100 short, thereby making it easy to respond to the high frequency properties, and the elasticity recovery time of the elastic part 150 is shortened, thereby shortening the test time. Furthermore, the actual width (t) of the electro-conductive contact pin 100 or the elastic part 150 is formed smaller than the entire thickness size H, thereby improving the bending resistance in the thickness direction.

A ratio of the entire thickness size H and the entire width size W of the electro-conductive contact pin 100 may be from 1:1 to 1:5, but is not limited thereto. As described above, the narrower pitch can be achieved by reducing the entire width size W of the electro-conductive contact pin 100. Furthermore, when a ratio of the entire thickness size H and the entire width size W of the electro-conductive contact pin 100 is 1:1, resistance to a moment acting in the thickness direction can be increased, and contact stability can be improved. Furthermore, current carrying capacity can be improved by increasing the entire thickness size H of the electro-conductive contact pin 100.

Next, the guide member 200 (hereinbelow, which will be referred to as ‘the guide member’) according to an embodiment of the present disclosure will be described.

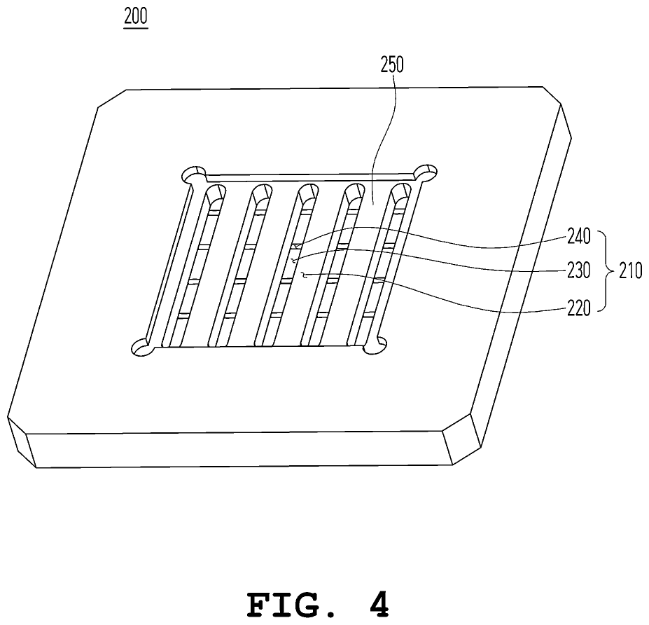

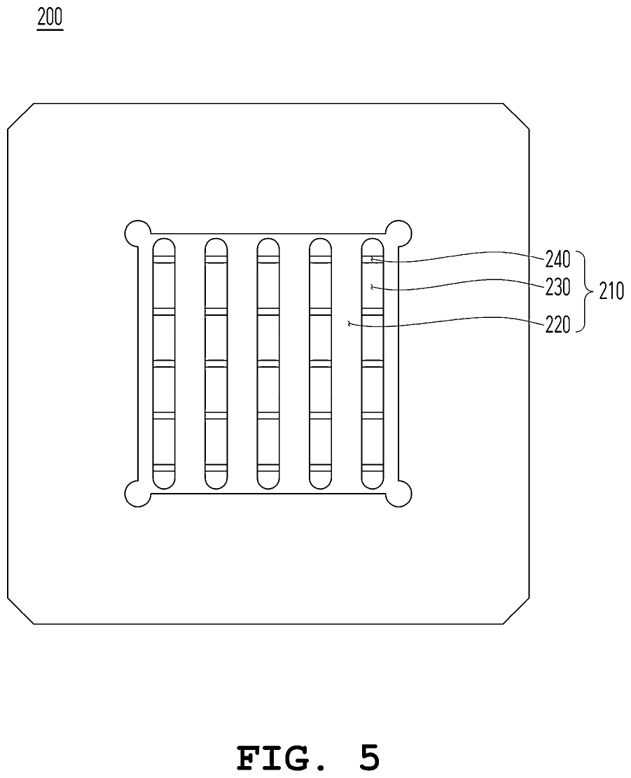

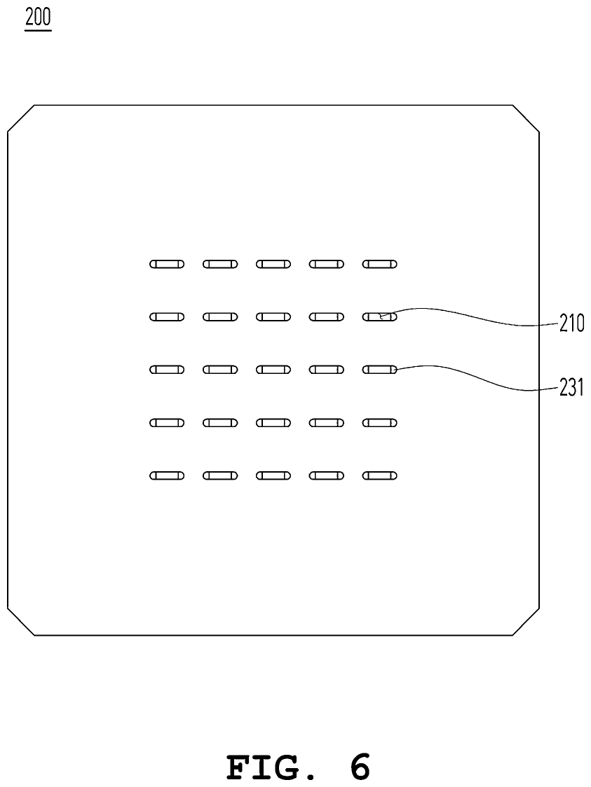

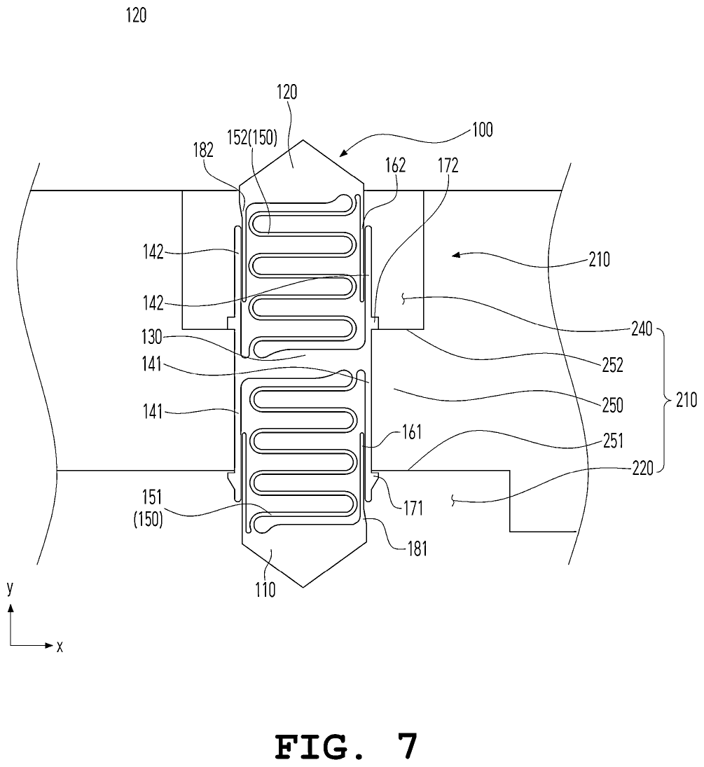

FIG. 4 is a view illustrating the entire shape of the guide member 200 according to the embodiment of the present disclosure. FIG. 5 is a view illustrating a lower surface of the guide member 200 according to the embodiment of the present disclosure. FIG. 6 is a view illustrating an upper surface of the guide member 200 according to the embodiment of the present disclosure. FIG. 7 is a view illustrating the guide member 200 to which the electro-conductive contact pin 100 is coupled in the embodiment of the present disclosure.

Referring to FIGS. 4 to 7, the electro-conductive contact pin 100 may be coupled to the guide member 200. The guide member 200 may include the through hole 210 containing the electro-conductive contact pin 100. The through hole 210 may include a third region 220 depressed along a first surface of the guide member 200 in a longitudinal direction, a second region 240 extending along a second surface of the guide member 200 in a width direction, and a first region 230 provided between the second region 240 and the third region 220 and extending in a thickness direction.

The longitudinal direction (±y direction), the width direction (±x direction), and the thickness direction (±z direction) of the guide member 200 may be understood as the above-described longitudinal direction, the above-described width direction, and the above-described thickness direction of the electro-conductive contact pin 100.

The third region 220 may be formed by being depressed in the longitudinal direction along a first surface (upper surface or lower surface) of the guide member 200. For example, the third region 220 may be formed such that at least a part of the lower surface of the guide member 200 is depressed in the upward direction (+y). The third region 220 may be a space in which at least a part of the electro-conductive contact pin 100 is contained. At least a part of the first elastic part 151 may be located in the third region 220.

The second region 240 may be formed by extending in the width direction (±x direction) along a second surface of the guide member 200 (lower surface or upper surface). For example, the second region 240 may be formed such that at least a part of the upper surface of the guide member 200 is depressed in the downward direction. The second region 240 may be a space in which at least a part of the electro-conductive contact pin 100 is contained. At least a part of the second elastic part 152 may be located in the second region 240.

A plurality of second regions 240 may be provided. Each second region 240 may have a width larger than the thickness thereof. The plurality of second regions 240 may be arranged in the thickness direction and/or the longitudinal direction.

The first region 230 may be provided between each second region 240 and the third region 220. The first region 230 may be formed by extending in the thickness direction (±z direction) along the guide member 200. The first region 230 may be a space in which at least a part of the electro-conductive contact pin 100 is contained. At least a part of the first elastic part 151 and at least a part of the second elastic part 152 may be located in the first region 230.

A plurality of first regions 230 may be provided. Each first region 230 may have a thickness larger than the width thereof. The plurality of first regions 230 may be arranged in the width direction.

The plurality of second regions 240 may communicate with one first region 230. The plurality of first region 230 may communicate with one third region 220. Accordingly, a plurality of through holes 210 may be provided and arranged in the longitudinal direction and/or the thickness direction.

The width of each second region 240 may be larger than the width of each first region 230 and smaller than the width of the third region 220. The width of each first region 230 may be smaller than the width of each second region 240 and smaller than the width of the third region 220. The width of the third region 220 may be larger than the width of each second region 240 and larger than the width of each first region 230.

The thickness of each second region 240 may be smaller than the thickness of each first region 230 and smaller than the thickness of the third region 220. The thickness of each first region 230 may be larger than the thickness of each second region 240 and smaller than the thickness of the third region 220. The thickness of the third region 220 may be larger than the thickness of each second region 240 and larger than the thickness of each first region 230.

The guide member 200 may include a fixing step 250. The fixing step 250 may be formed by protruding from each first region 230 of the guide member 200 (or the through hole 210) in the width direction (±x direction). The width of each first region 230 is formed smaller than the width of each second region 240 and the width of each first region 230, so that the fixing step 250 protruding in the width direction may be provided. A plurality of fixing steps 250 may be provided. One fixing step 250 may be provided in one through hole 210. Each fixing step 250 may limit the vertical movement of the electro-conductive contact pin 100. Herein, limitation means limiting separation of the electro-conductive contact pin 100, and predetermined movement may be allowed. The details will be described below.

The guide member 200 may be made of a silicon nitride (Si3N4) material, but is not limited thereto. The guide member 200 may be formed with a thickness (y-axial length) of 1 mm, but is not limited thereto. The third region 220 may be formed into a groove shape first, each first region 230 may be formed, and then each second region 240 may be formed continuously.

The through hole 210 may have the structure including the third region 220, each first region 230, and each second region 240, and each region are formed in separate phases, so that the guide member 200 may include the through hole 210 with a vertical inner wall. Moreover, the guide member 200 may be formed to have the through hole 210 with the vertical inner wall and relatively thick, so the durability thereof may be strengthened.

Unlike the above descriptions, the through hole 210 of the guide member 200 may include only each first region 230 and each second region 240. The first region 230 may be formed by extending in the thickness direction along the guide member 200. Each second region 240 may be provided at an upper portion of each first region 230 and formed by extending in the width direction along a first surface (e.g., upper surface) of the guide member 200. The guide member 200 may be configured the same as the above descriptions except that the third region 220 is not provided. Herein, the through hole 210 may include a lower first region 230 and an upper second region 240.

Next, the inspection device 10 (hereinbelow, ‘the inspection device’) according to an embodiment of the present disclosure will be described.

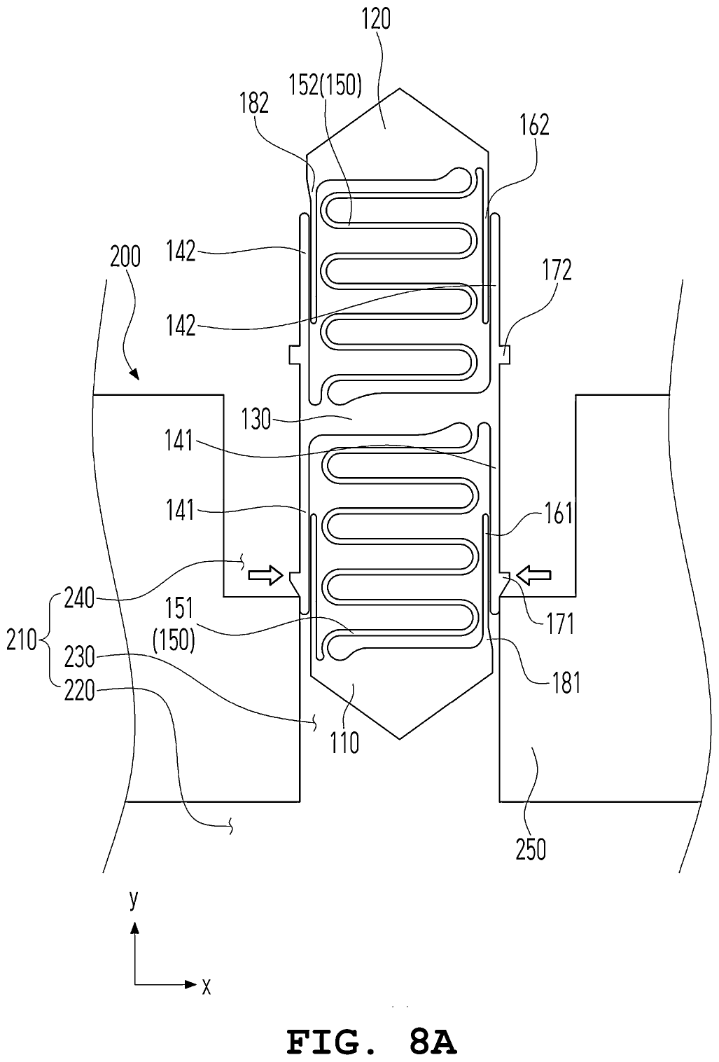

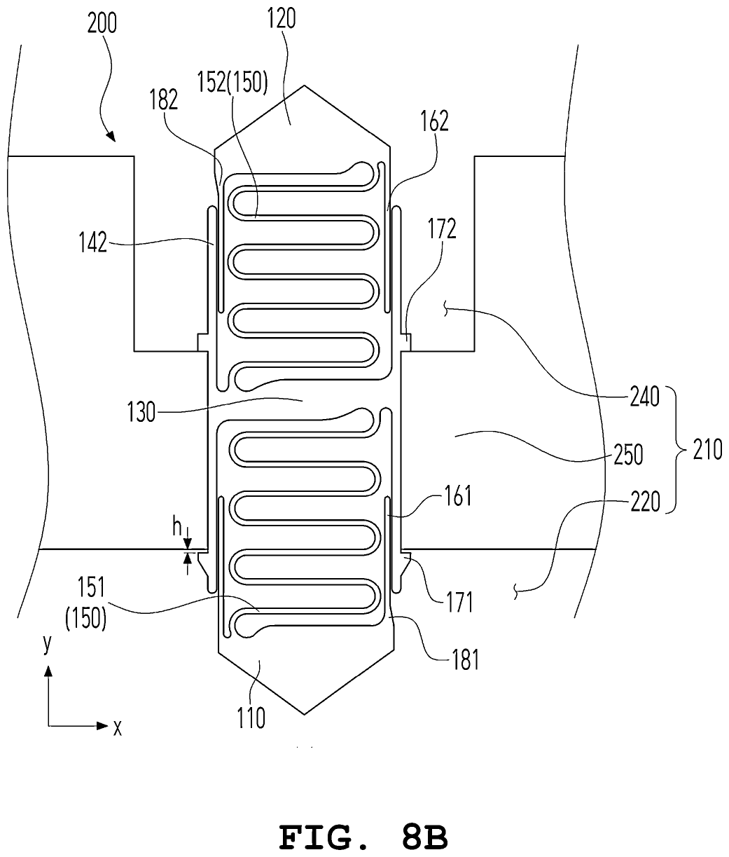

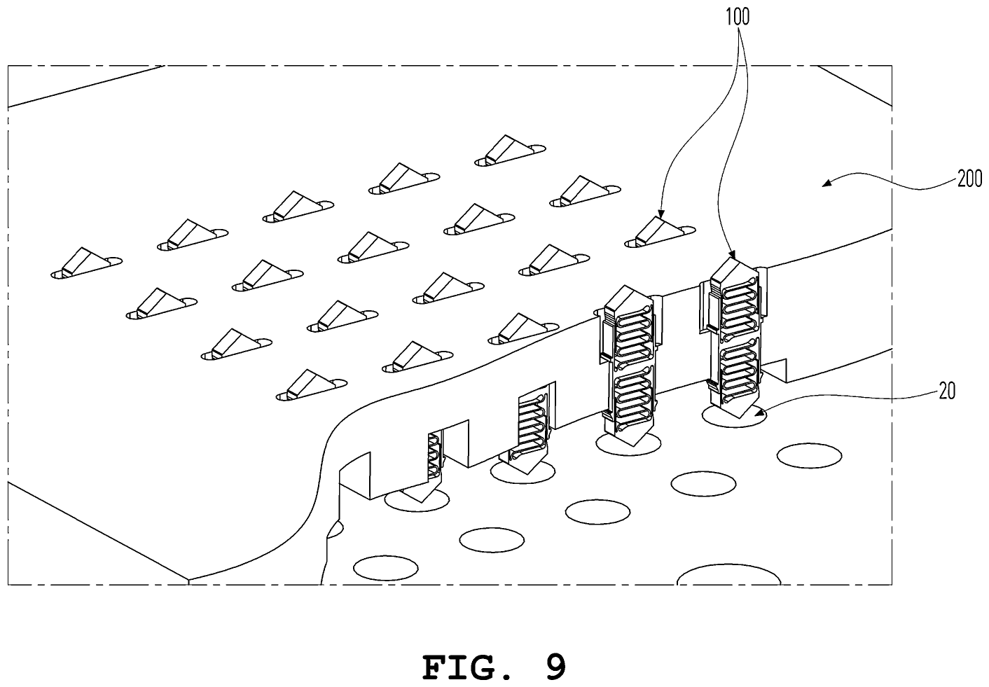

FIG. 8A is a view illustrating the inspection device 10 before the electro-conductive contact pin 100 is coupled to the guide member 200 in the present disclosure. FIG. 8A is a view illustrating the inspection device 10 after the electro-conductive contact pin 100 is coupled to the guide member 200 in the embodiment of the present disclosure. FIG. 9 is a view illustrating the inspection device 10 according to the embodiment of the present disclosure and a partial section thereof.

Referring to FIGS. 8A and 8B, the inspection device 10 may inspect electrical properties of the inspection object. The inspection device 10 may include the electro-conductive contact pin 100 and the guide member 200.

The electro-conductive contact pin 100 may include the first connection part 110 constituting the lower part, the second connection part 120 constituting the upper part, and the elastic part 150 connecting the first connection part 110 and the second connection part 120 to each other. Furthermore, the electro-conductive contact pin 100 may include the division part 130, the support part 140, the first extension part 161, and the second extension part 162. The structures and the properties of elements constituting the electro-conductive contact pin 100 may be understood as the same as described above.

The electro-conductive contact pin 100 may include a first locking step 171 protruding in the width direction on a first location of the electro-conductive contact pin 100 and a second locking step 172 protruding in the width direction on a second location of the electro-conductive contact pin 100. The first locking step 171 may be provided at the first support part 141 of the electro-conductive contact pin 100. The second locking step 172 may be provided at the second support part 142 of the electro-conductive contact pin 100. Herein, the first locking step 171 may be formed with the width (x-axial length) shortened as it does downward.

The guide member 200 may include the through hole 210 including each second region 240, each first region 230, and the third region 220. The guide member 200 may include the fixing step 250 formed by each second region 240, each first region 230, and the third region 220.

The guide member 200 may include the through hole 210 including each first region 230 and each second region 240. The guide member 200 may include the fixing step 250 formed by each first region 230 and each second region 240. Herein, the first region 230 may be formed by extending in the thickness direction along the guide member 200. Each second region 240 may be provided at an upper portion of each first region 230 and formed by extending in the width direction along a first surface (upper surface) of the guide member 200. Herein, the fixing step 250 may be formed as the width of each first region 230 is smaller than the width of each second region 240.

Continuing to refer to FIG. 8A, the electro-conductive contact pin 100 may be fixed to the guide member 200 through the through hole 210. The electro-conductive contact pin 100 may pass through the fixing step 250 (the first region 230) in the longitudinal direction (−y direction) as the first locking step 171 is moved inward in the width direction (±x direction). The first locking step 171 is brought into contact with the fixing step 250 to be moved in the width direction and coupled to the guide member 200 in a slidingly moving manner.

Referring to FIGS. 7 and 8B again, a lower surface 251 of the fixing step 250 may be brought into contact with the first locking step 171 to limit separation of the electro-conductive contact pin 100. The fixing step 250 may limit the movement of the electro-conductive contact pin 100 in the longitudinal direction (+y direction). An upper surface 252 of the fixing step 250 may be brought into contact with the second locking step 172 to limit separation of the electro-conductive contact pin 100. The fixing step 250 may limit the movement of the electro-conductive contact pin 100 in the longitudinal direction (−y direction). Specifically, the fixing step 250 may limit the electro-conductive contact pin 100 from being moved by more than a protruding length (h) which will be described below.

While the electro-conductive contact pin 100 is coupled to the guide member 200, the elastic part 150 may be located between the upper surface and the lower surface of the guide member 200. In other words, the elastic part 150 may be coupled to the guide member 200 without being exposed to the upper space and the lower space.

While the electro-conductive contact pin 100 is coupled to the guide member 200, the first locking step 171 and the second locking step 172 may be located between the upper surface and the lower surface of the guide member 200. The first locking step 171 may be located in the third region 220, and the second locking step 172 may be located in each second region 240. Accordingly, as the first locking step 171 and the second locking step 172 are blocked from contact with external elements, the electro-conductive contact pin 100 may be solidly coupled to the guide member 200.

The first locking step 171 may be provided at the first location of the electro-conductive contact pin 100. The first location may mean the height of the uppermost end part of the first locking step 171. The second locking step 172 may be provided at the second location at an electro-conductive contact tip. The second location may mean the height of the lowermost end part of the second locking step 172.

While the electro-conductive contact pin 100 and the guide member 200 are coupled to each other, a part (specifically, the lower part) of the first support part 141 including the first locking step 171 may be provided in a protruding state from the lower surface 251 of the fixing step 250. While the electro-conductive contact pin 100 and the guide member 200 are coupled to each other, a part (specifically, the upper part) of the second support part 142 including the second locking step 172 may be provided in a protruding state from the upper surface 252 of the fixing step 250.

The distance between the first location and the second location may be larger than the length of the fixing step 250. Accordingly, the support part 140 is formed larger than the length of the fixing step 250, and at least a part of the support part 140 may protrude outward of the fixing step 250 (or the first region 230).

The support part 140 may ensure a contact stroke of the terminals 20 through the length of protruding outward of the fixing step 250. Due to the protruding length (h), the support part 140 may ensure an available space equal to the protruding length (h) from the upper surface 252 or the lower surface 251 of the fixing step 250. Accordingly, the electro-conductive contact pin 100 may be moved in the longitudinal direction within the available space provided due to the protruding length (h) when compressed by the terminals 20 and moved downward or upward.

The electro-conductive contact pin 100 may ensure contact stroke through the protruding length (h) with an upper end part or a lower end part of the support part 140 protruding outward of the fixing step 250. Accordingly, the electro-conductive contact pin 100 may be brought into contact with the terminals 20, and then be entirely moved in the longitudinal direction through the protruding length (h) of the support part 140, thereby preventing damage.

The protruding length (h) may be formed larger than or equal to 5 μm and less than or equal to 50 μm. When the protruding length (h) is less than 5 μm, there is a problem in that it is difficult to ensure contact stroke of the terminals 20, and when the protruding length (h) exceeds 50 μm, excessive deformation of the electro-conductive contact pin 100 may be induced or the support part 140 may be damaged. However, the protruding length (h) is not necessarily limited to the above description.

The entire elastic part 150 of the electro-conductive contact pin 100 may be contained in the through hole 210. The elastic part 150 may be contained throughout each second region 240, each first region 230, and the third region 220. Herein, only the first connection part 110 and the second connection part 120 may be exposed outward of the through hole 210. Accordingly, the inspection device 10 may prevent foreign materials from being introduced into the elastic part 150.

Referring to FIG. 9, the inspection device 10 according to the embodiment of the present disclosure may include a plurality of through holes 210 and a plurality of electro-conductive contact pins 100. The plurality of through holes 210 may be aligned in the width direction and the thickness direction of the guide member 200. Each electro-conductive contact pin 100 may be contained in each through hole 210. Accordingly, the inspection device 10 may be brought into contact with the terminal 20 to provide or receive an elastic signal.

Although the preferred embodiments of the present disclosure have been described for illustrative purposes, those skilled in the art will appreciate that various modifications, additions and substitutions are possible, without departing from the scope and spirit of the present disclosure as disclosed in the accompanying claims.

1. A guide member to which an electro-conductive contact pin is coupled, the guide member comprising:
a through hole containing the electro-conductive contact pin,
wherein the through hole comprises:
a first region formed by extending in a thickness direction along the guide member; and
a second region provided on the first region and formed by extending in a width direction along one surface of the guide member.

2. The guide member of claim 1, wherein the second region includes a plurality of second regions and the plurality of second regions is arranged in the thickness direction,
the first region includes a plurality of first regions and the plurality of first regions is arranged in the width direction, and
the plurality of second regions communicates with the first region to form a plurality of through holes.

3. An inspection device for inspecting electrical properties of an inspection object, the inspection device comprising:
an electro-conductive contact pin sending an electrical signal to the inspection object; and
a guide member comprising a through hole containing the electro-conductive contact pin,
wherein the electro-conductive contact pin comprises a first connection part constituting a lower part, a second connection part constituting an upper part, and an elastic part connecting the first connection part and the second connection part to each other,
wherein the through hole comprises:
a first region formed by extending in a thickness direction along the guide member; and
a second region provided on the first region and formed by extending in a width direction along one surface of the guide member.

4. The inspection device of claim 3, wherein the elastic part is located between an upper surface and a lower surface of the guide member.

5. The inspection device of claim 3, wherein the guide member comprises a fixing step formed by the first region and the second region, and
the electro-conductive contact pin further comprises: a first locking step formed by protruding in the width direction at a first location of the contact pin; and a second locking step formed by protruding in the width direction at a second location of the contact pin,
an upper surface of the fixing step is in contact with the second locking step to limit separation of the electro-conductive contact pin, and
a lower surface of the fixing step is in contact with the first locking step to limit separation of the electro-conductive contact pin.

6. The inspection device of claim 5, wherein the first locking step moves inward in the width direction to pass through the first region in a longitudinal direction.

7. An electro-conductive contact pin comprising:
a division part extending in a width direction;
a support part extending in a longitudinal direction from either side of the division part;
a first connection part provided at a lower part of the division part;
a second connection part provided at an upper part of the division part;
a first extension part extending in the longitudinal direction from either side of the first connection part;
a second extension part extending in a longitudinal direction from either side of the second connection part; and
an elastic part connecting the division part and the first connection part to each other and connecting the division part and the second connection part to each other,
wherein when the elastic part is compressed, a current path is formed by at least one of contact between the support part and the first extension part and contact between the support part and the second extension part.

8. The electro-conductive contact pin of claim 7, wherein the first extension part is formed by being spaced apart from the support part along an inner surface of the support part,
the second extension part is formed by being spaced apart from the support part along the inner surface of the support part, and
the first extension part and the second extension part are in contact with the support part to limit the width-directional excessive deformation of the electro-conductive contact pin.

9. The electro-conductive contact pin of claim 7, wherein the first extension part comprises a 1-1 extension part extending from a first side of the first connection part and a 1-2 extension part extending from a second side of the first connection part,
at least one of the 1-1 extension part and the 1-2 extension part comprises a first contact part bent in the width direction, and
the first contact part is contactable with the support part according to compression of the elastic part.

10. The electro-conductive contact pin of claim 9, wherein the second extension part comprises a 2-1 extension part extending from a first side of the second connection part and a 2-2 extension part extending from a second side of the second connection part,
at least one of the 2-1 extension part and the 2-2 extension part comprises a second contact part bent in the width direction, and
the second contact part is contactable with the support part according to compression of the elastic part.
